(19) United States
(12) Patent Application Publication
(10) Pub. No.: US 2026/0190428 A1
(43) Pub. Date: Jul. 2, 2026

(54) CHALCOGEN-DOPED NMOS SOURCE AND DRAIN CONTACTS

(71) Applicant: Intel Corporation, Santa Clara, CA (US)

(72) Inventors: Ilya V. Karpov, Portland, OR (US); Wenshen Li, Fremont, CA (US); Aaron A. Budrevich, Portland, OR (US); Matthew V. Metz, Portland, OR (US); Arnab Sen Gupta, Hillsboro, OR (US); Gilbert Dewey, Beaverton, OR (US); David Kohen, Hillsboro, OR (US)

(73) Assignee: Intel Corporation, Santa Clara, CA (US)

(21) Appl. No.: 19/003,427

(22) Filed: Dec. 27, 2024

(51) Int. Cl. H10D 64/62; H10D 62/60; H10D 62/834; H10D 64/23

(52) U.S. Cl. CPC H10D 64/62; H10D 62/60; H10D 62/834; H10D 64/251

(57) ABSTRACT

The surfaces of NMOS (n-type metal-oxide-semiconductor) transistor epitaxial source and drain regions are heavily doped with an n-type chalcogen (e.g., tellurium, selenium, sulfur) to overcome the limitations of low-ionization energy n-type dopants (e.g., phosphorous, arsenic, antimony) to free-electron concentrations due to Fermi-level pinning. The chalcogen can be introduced to the source or drain region surfaces by diffusion from a chalcogen-rich metal contact layer or by chemical vapor deposition processes in which a chalcogen precursor flows over the source and drain regions after they are formed. In some embodiments, the chemical vapor deposition process can comprise silicon and chalcogen precursors flowing over the source and drain region surfaces to form a thin layer of silicon highly doped with a chalcogen.

### BACKGROUND

The contribution of low-ionization energy n-type dopants, such as phosphorous, to the free-electron concentration at n-channel metal-oxide-silicon (NMOS) transistor source and drain regions surfaces is limited due to Fermi-level pinning. Fermi-level pinning occurs when the position of the Fermi level at the interface between a semiconductor and a metal becomes “pinned” and does not align as predicted by the work functions of the materials. This phenomenon is caused by interface states, such as defects or localized energy levels, that dominate electronic behavior at the interface.

### BRIEF DESCRIPTION OF THE DRAWINGS

FIGS. 1A-1C are cross-sectional views of NMOS source and drain regions at various stages of a first example processing sequence.

FIGS. 2A-2D are cross-sectional views of NMOS source and drain regions at various stages of a second example processing sequence.

FIG. 3 is a first example method of forming chalcogen-doped NMOS source and drain contacts.

FIG. 4 is a second example method of forming chalcogen-doped NMOS source and drain contacts.

FIG. 5 is a top view of a wafer and dies in which any of the chalcogen-doped source and drain regions disclosed herein may be included.

FIG. 6 is a cross-sectional view of an integrated circuit structure that may include any of the chalcogen-doped source and drain regions disclosed herein.

FIGS. 7A-7D are perspective views of example planar, FinFET, gate-all-around, and stacked gate-all-around transistors.

FIG. 8 is a cross-sectional view of an integrated circuit device assembly that may include any of the chalcogen-doped source or drain regions disclosed herein.

FIG. 9 is a block diagram of an example electrical device that may include any of the chalcogen-doped source or drain regions disclosed herein.

### DETAILED DESCRIPTION

Source and drain contacts for NMOS (n-channel metal-oxide-semiconductor) field effect transistors are typically made to epitaxially grown silicon layers doped with an n-type dopant, usually phosphorous. The contribution of low-ionization energy n-type dopants (such as phosphorous, arsenic, and antimony) to the free-electron concentration at the surfaces of NMOS source and drain regions is limited due to Fermi-level pinning. Thus, the contribution of parasitic resistance of NMOS source and drain region surfaces to overall parasitic contact resistances may increase as transistor geometries continue to shrink. This can cause negative effects on NMOS transistor performance.

Disclosed herein are NMOS source and drain regions doped with an n-type chalcogen dopant (e.g., tellurium, selenium, sulfur) at the source and drain region surfaces, where the source and drain regions interface with metal contacts. Chalcogens have a generally higher ionization energy than the n-type dopants typically usually used in NMOS source and drain regions (e.g., phosphorous, arsenic). The contribution of higher ionization n-type dopants to free-electron concentrations at source and drain region surfaces does not suffer from the same limitation as lower-ionization n-type dopants. Thus, the introduction of n-type chalcogen dopants at the surfaces of NMOS source and drain regions may provide the advantage of reducing parasitic contact resistance, which can result in higher-performing NMOS transistors.

The chalcogen used to dope NMOS source and drain region surfaces can be tellurium, selenium, or sulfur. Chalcogen dopants can be introduced into NMOS source and drain surfaces by diffusion from a metal contact layer. The metal contact layer can comprise a chalcogen along with titanium or other suitable metal (e.g., a metal having a low work function). In some embodiments, the metal contact layer comprises phosphorous or other n-type dopant. The n-type dopant used in the metal contact layer can be the same as or different from the n-type dopant used in the NMOS source and drain regions (e.g., phosphorous). The metal contact layers comprising a chalcogen can be formed by sputtering a single target comprising a metal and a chalcogen, or co-sputtering two targets, one comprising the contact metal and the other comprising a chalcogen. Alternatively, a chalcogen can be introduced into source and drain region surfaces by chemical vapor deposition after epitaxial growth of the source and drain regions. For example, a chemical vapor deposition process can comprise flowing a chalcogen precursor over the source and drain regions, after the regions have been grown epitaxially, to deposit a chalcogen on the surfaces with a chalcogen. In another example, a chemical vapor deposition process can comprise flowing silicon and chalcogen precursors over source and drain region surfaces to form a thin chalcogen-doped layer of silicon over the source and drain regions. In yet another example, the chemical vapor deposition process can comprise flowing silicon, chalcogen, and n-type dopant (e.g., phosphorous) precursors to yield a thin surface layer comprising silicon, a chalcogen, and an n-type dopant.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner.

The term “connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, layers, faces, or features that are referred to as being substantially parallel can refer to layers, faces, or features that are within a few degrees of being parallel with each other; layers, faces, or features that are referred to as being substantially perpendicular to each other can refer to features that are within +/−15 degrees of being perpendicular to each other. Further, recited numerical or percentage values (including those recited as starting and ending values for a range of numbers or percentages) preceded by the word “about” includes numerical or percentage values within +/−10% of the recited numerical or percentage value.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are arranged next to each other (e.g., side-by-side, top and bottom).

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the phrase “electrically coupled” refers to the presence of one or more electrically conductive paths between components that are recited as being electrically coupled.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

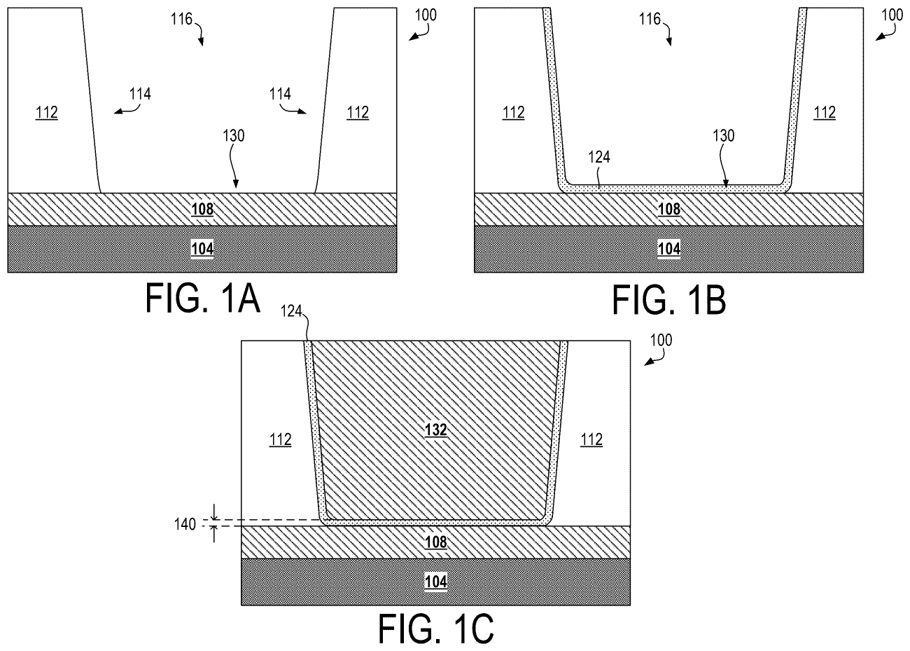

FIGS. 1A-1C are cross-sectional views of NMOS source and drain regions at various stages of a first example processing sequence. FIG. 1A illustrates a structure 100 comprising a substrate 104, an epitaxial silicon layer comprising an n-type dopant (epitaxial layer 108), and regions of an isolation layer (isolation regions 112). A trench 116 has been formed in the isolation layer by a suitable etch process. The substrate 104 can comprise silicon and can be a bulk silicon wafer, a silicon-on-insulator wafer, or another suitable substrate. The n-type dopant can be phosphorous, arsenic, or antimony. In some embodiments, the epitaxial layer 108 can be grown with doping of the epitaxial layer 108 occurring during epitaxial growth of the layer (e.g., in situ doping).

The isolation regions 112 can comprise any suitable nitride or oxide, such as silicon dioxide (SiO₂, which is a material that comprises silicon and oxygen), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen), or silicon nitride (SiₓN_{y} (e.g., Si₃N₄), which is a material that comprises silicon and nitrogen).

FIG. 1B illustrates the structure 100 after formation of a metal contact layer 124. A first portion of the metal contact layer 124 is located on the epitaxial layer 108 and second portions of the metal contact layer 124 are located on sidewalls 114 of the isolation regions 112. The metal contact layer 124 comprises a chalcogen and a metal. The chalcogen can be tellurium, selenium, or sulfur. The metal can be titanium, tantalum, tungsten, scandium, zirconium, aluminum, or another suitable metal or alloy. In some embodiments, the metal contact layer 124 further comprises a n-type dopant. The n-type dopant can be the same as or different from the n-type dopant used in the epitaxial layer 108. Thus, in some embodiments, the metal contact layer 124 can comprise titanium, tellurium, and phosphorous and the epitaxial layer 108 can comprise phosphorous. In other embodiments, the metal contact layer 124 can comprise titanium, selenium, and phosphorous and the epitaxial layer 108 can comprise phosphorous. In some embodiments, the portion of the metal contact layer 124 located on the epitaxial layer 108 can have a thickness 140 of about three nanometers or less, or about two nanometers or less. In some embodiments, the thickness of the portions of the metal contact layer 124 located on the sidewalls 114 of the isolation regions 112 can be thinner than the thickness of the portion of the metal contact layer 124 located on the epitaxial layer 108. In some embodiments, the metal contact layer 124 is selectively deposited on a surface 130 of the epitaxial layer 108 and does not comprise portions that are located on the sidewalls 114.

In some embodiments, a metal contact layer can be formed by chemical vapor deposition (CVD), plasma-enhanced chemical vapor deposition (PECVD), atomic layer deposition (ALD), physical vapor deposition (e.g., sputtering), or another suitable deposition or thin film formation process. In some embodiments of forming the metal contact layer, where the metal contact layer is formed via sputtering, a single sputtering target comprising a metal contact layer metal (any of the metals disclosed herein as being used to form a metal contact layer) and a chalcogen is used. In some embodiments, the target can further comprise an n-type dopant, such as phosphorous.

In other embodiments where the metal contact layer is formed via sputtering, the metal contact layer is formed via co-sputtering of two targets, with one of the sputtering targets comprising a metal contact layer metal and the other sputtering target comprising a chalcogen. In some embodiments, either of the targets used in a co-sputtering process to form the metal contact layer can comprise phosphorous or another n-type dopant. Any sputtering target comprising a chalcogen can comprise from about 10% to about 50% of the chalcogen by weight. In embodiments where sputtering is used to form the metal contact layer and the target comprises phosphorous, the target can comprise from about 1% to about 20% phosphorous by weight or from about 1% to about 50% phosphorous by weight. In embodiments where the metal contact layer 124 is co-sputtered, the metal contact layer can be formed by sputtering both targets (one comprising a metal, one comprising a chalcogen) to form a first sub-layer comprising a chalcogen and then sputtering just the target comprising the metal to form a second sub-layer that does not comprise a chalcogen.

In embodiments where the metal contact layer 124 comprises chalcogen, there exists a gradient in chalcogen concentration at the metal contact layer-epitaxial layer interface, and the chalcogen will diffuse into the epitaxial layer 108 during subsequent thermal processing (e.g., downstream annealing steps). This can create a chalcogen-doped region in the epitaxial layer 108 in the vicinity of the metal contact layer-epitaxial interface (i.e., at the surface of the epitaxial layer 108), which can result in higher free electron concentrations in the epitaxial layer 108 in the vicinity of the interface than is possible with low-ionization dopants (e.g., phosphorous).

FIG. 1C illustrates the structure 100 after the trench 116 has been filled by a metal (fill metal 132). The fill metal 132 can be formed by chemical vapor deposition (CVD), plasma-enhanced chemical vapor deposition (PECVD), physical vapor deposition (e.g., sputtering), or other suitable fill process. The fill metal 132 can comprise tungsten, cobalt, titanium, gold, aluminum, molybdenum, chromium, nickel, or another suitable metal or alloy. In some embodiments, a barrier layer to protect the metal contact layer 124 from oxygen and other contaminants can be formed on the metal contact layer 124 before fill of the trench 116 by the fill metal 132. The barrier layer is positioned between the metal contact layer 124 and the fill metal 132 and can comprise tantalum (Ta), tantalum nitride (which is a material that comprises titanium and nitrogen (e.g., TaN, Ta₂N, Ta₃N₅)), indium oxide (In₂O₃, which is a material that comprises indium and oxygen), tungsten nitride (which is a material that comprises tungsten and nitrogen (e.g., W₂N, WN, WN₂), titanium nitride (TiN, which is a material that comprises titanium and nitrogen), ruthenium, or another suitable material.

In some embodiments of forming NMOS source and drain regions as illustrated by FIGS. 1A-1C, the source and drain region surfaces become doped with chalcogen via a delta-doping chemical vapor deposition process. In such a process, a chalcogen precursor flows over a surface 130 of the epitaxial layer 108, resulting in chalcogen being deposited on the surface 130. As part of the chemical vapor deposition process and/or during subsequent thermal processing, the chalcogen can diffuse into the epitaxial layer 108, creating a chalcogen-doped surface region. In some embodiments of delta-doping the surface of the epitaxial layer 108, the metal contact layer 124 is formed without chalcogen.

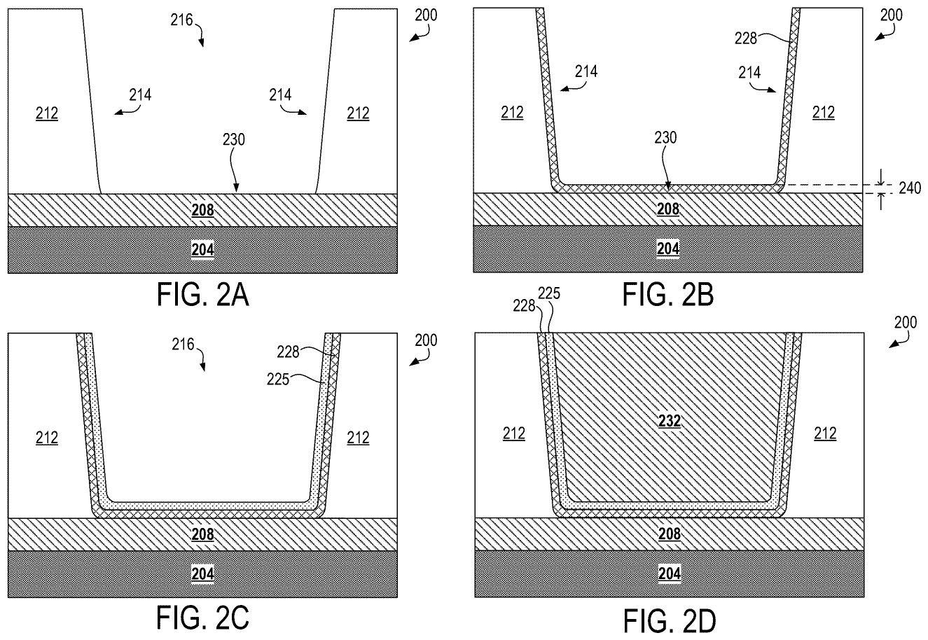

FIGS. 2A-2D are cross-sectional views of NMOS source and drain regions at various stages of a second example processing sequence. The processing sequence illustrated in FIGS. 2A-2D is similar to that illustrated in FIGS. 1A-1C, with features in FIGS. 2A-2D described by the descriptions for their similarly-numbered counterpart feature in FIGS. 1A-1C (e.g., substrate 204 is described by the description for substrate 104). One exception is that the processing sequence illustrated in FIGS. 2A-2D comprises a surface layer comprising silicon and a chalcogen located between a metal contact layer and the epitaxial layer.

FIG. 2A illustrates a structure 200 comprising a substrate 204, an n-type epitaxial silicon layer (epitaxial layer 208), isolation regions 212, and a trench 216. FIG. 2B illustrates the structure 200 after formation of a surface layer 228, a first portion of which is located on a surface 230 of the epitaxial layer 208 and second portions of which are located on sidewalls 214 of the isolation regions 212. The surface layer 228 comprises silicon and a chalcogen, such as tellurium, selenium, or sulfur. The first portion of the surface layer 228 can have a thickness 240 of about five nanometers or less. In some embodiments, the thickness of the portions of the surface layer 228 located on the sidewalls 214 of the isolation regions 212 can be thinner than the thickness of the portion of the surface layer 228 located on the epitaxial layer 208. In some embodiments, the surface layer 228 is selectively deposited on a surface 230 of the epitaxial layer 208 and does not comprise portions that are located on the sidewalls 214.

In some embodiments, the surface layer 228 is formed via a chemical vapor deposition process in which a silicon precursor and a chalcogen precursor are flowed over the surface 230 of the epitaxial layer 208. In some embodiments, the chalcogen precursor can be derived from the family of X(SiH₃)₂ precursors, where X is a chalcogen (e.g., Te, Se, S).

FIG. 2C illustrates the structure 200 after formation of a metal contact layer 225 on the surface layer 228. The metal contact layer 225 comprises a first portion located on a surface 230 of the epitaxial layer 208 and second portions located on sidewalls 214 of the isolation regions 212. The metal contact layer 225 comprises any of the metals described above that can form the metal contact layer 124 and does not comprise chalcogen. The metal contact layer 225 can comprise an n-type dopant and can be formed via a sputtering process utilizing one or two sputtering targets. In embodiments where one target is used, the target can comprise a metal and can optionally comprise an n-type dopant. In embodiments where two targets are used, one target can comprise a metal and the other target can comprise an n-type dopant. The first portion of the metal contact layer 225 can have a thickness 240 of about five nanometers or less. In some embodiments, the thickness of the portions of the metal contact layer 225 located on the sidewalls 214 of the isolation regions 212 can be thinner than the thickness of the portion of the metal contact layer 225 located over the epitaxial layer 208. In some embodiments, the metal contact layer 225 is selectively deposited over the surface 230 of the epitaxial layer 208 and does not comprise portions that are located on the sidewalls 214.

FIG. 2D illustrates the structure 200 after the trench 216 has been filled by a fill metal 232. In some embodiments, a barrier layer to protect the metal contact layer 225 from oxygen and other contaminants can be formed on the metal contact layer 225 before fill of the trench 216 by the fill metal 232. The barrier layer can be positioned between the metal contact layer 225 and the fill metal 232 and can comprise the same materials as the barrier layer described above in the discussion of FIGS. 1A-1C.

As a result of forming chalcogen-doped NMOS source and drain regions as described herein, the atomic composition of the metal contact layer and/or the source and drain regions can be as described in the following examples.

In a first example, the epitaxial layer and/or the metal contact layer comprises an atomic composition of at least about 5% of a chalcogen at an interface between the epitaxial layer and the metal contact layer.

In a second example, the epitaxial layer comprises an atomic composition comprising from about 5% to about 50% of a chalcogen at an interface between the epitaxial layer and the metal contact layer.

In a third example, the metal contact layer comprises an atomic composition comprising from about 5% to about 50% of a chalcogen at an interface between the epitaxial layer and the metal contact layer.

In a fourth example, the epitaxial layer comprises an atomic composition comprising at least about 5% of a chalcogen at a point one nanometer into the epitaxial layer from the interface between the epitaxial layer and the metal contact layer.

In a fifth example, the epitaxial layer comprises an atomic composition comprising at least about 5% of a chalcogen at a point three nanometers into the epitaxial layer from the interface between the epitaxial layer and the metal contact layer.

In a sixth example, the epitaxial layer comprises an atomic composition comprising at least about 5% of a chalcogen at a point five nanometers into the epitaxial layer from the interface between the epitaxial layer and the metal contact layer.

In a seventh example, the epitaxial layer comprises an atomic composition comprising at least about 5% of a chalcogen at an interface between the epitaxial layer and the metal contact layer, and less than 5% of the chalcogen and from about 5% to about 20% phosphorous at a point one nanometer into the epitaxial layer from the interface between the epitaxial layer and the metal contact layer.

In an eighth example, the epitaxial layer comprises an atomic composition comprising at least about 5% of a chalcogen at an interface between the epitaxial layer and the metal contact layer, and less than about 5% of the chalcogen and from about 5% to about 20% phosphorous at a point two nanometers into the epitaxial layer from the interface between the epitaxial layer and the metal contact layer.

In a ninth example, the epitaxial layer comprises an atomic composition comprising at least about 5% of a chalcogen at an interface between the epitaxial layer and the metal contact layer, and less than about 5% of the chalcogen and from about 5% to about 20% phosphorous at a point five nanometers into the epitaxial layer from the interface between the epitaxial layer and the metal contact layer.

In a tenth example, the epitaxial layer comprises an atomic composition comprising at least about 5% of a chalcogen at an interface between the epitaxial layer and the metal contact layer, and less than about 0.01% of the chalcogen and from about 5% to about 20% phosphorous at a point 10 nanometers into the epitaxial layer from the interface between the epitaxial layer and the metal contact layer.

In an eleventh example, the epitaxial layer comprises an atomic composition comprising at least about 5% of a chalcogen at an interface between the epitaxial layer and the metal contact layer, and less than about 0.01% of the chalcogen and from about 5% to about 20% phosphorous at a point 15 nanometers into the epitaxial layer from the interface between the epitaxial layer and the metal contact layer.

In a twelfth example, the epitaxial layer comprises an atomic composition comprising at least about 5% of a chalcogen at an interface between the epitaxial layer and the metal contact layer, and less than about 0.01% of the chalcogen and from about 5% to about 20% phosphorous at a point 20 nanometers into the epitaxial layer from the interface between the epitaxial layer and the metal contact layer.

In a thirteenth example, the epitaxial layer comprises an atomic composition comprising at least about 30% of a chalcogen at an interface between the epitaxial layer and the metal contact layer and an atomic composition comprising no more than 5% of a chalcogen at a point into the metal contact layer one nanometer from the interface.

In a fourteenth example, the epitaxial layer comprises an atomic composition comprising at least 30% of a chalcogen at an interface between the epitaxial layer and the metal contact layer and an atomic composition comprising no more than about 5% of a chalcogen at a point into the metal contact layer two nanometers from the interface.

In a fifteenth example, the epitaxial layer comprises an atomic composition comprising at least about 30% a chalcogen at an interface between the epitaxial layer and the metal contact layer and an atomic composition comprising no more than about 5% of a chalcogen at a point into the metal contact layer 10 nanometers from the interface.

In a sixteenth example, the metal contact layer comprises an atomic composition comprising a first percentage of a metal contact layer metal, a second percentage of a chalcogen, and a third percentage of phosphorous, wherein the second percentage is less than the first percentage and greater than the third percentage.

In a seventeenth example, at the interface between the epitaxial layer and the metal contact layer, the epitaxial layer has an atomic composition comprising a first percentage of a chalcogen and a second percentage of an n-type dopant, wherein the first percentage is at least twice the second percentage.

In an eighteenth example, an atomic composition of the metal contact layer, at the interface between the epitaxial layer and the metal contact layer, comprises at least about 60% of the metal and less than about 40% of a chalcogen.

In a nineteenth example, an atomic composition of the metal contact layer, at the interface between the epitaxial layer and the metal contact layer, comprises at least about 50% of the metal and less than about 50% of a chalcogen.

In a twentieth example, an atomic composition of the metal contact layer, at the interface between the epitaxial layer and the metal contact layer, comprises from about 55% to about 80% of the metal and from about 20% to about 45% of a chalcogen.

In a twenty-first example, an atomic composition of the metal contact layer, at the interface between the epitaxial layer and the metal contact layer, comprises from about 60% to about 75% of the metal and from about 25% to about 40% of a chalcogen.

In a twenty-second example, an atomic composition of the metal contact layer, at the interface between the epitaxial layer and the metal contact layer comprises about 60% of the metal and about 40% of a chalcogen.

In a twenty-third example, an atomic composition of the metal contact layer, at the interface between the epitaxial layer and the metal contact layer comprises about 67% of the metal and about 33% of a chalcogen.

In a twenty-fourth example, an atomic composition of the metal contact layer, at the interface between the epitaxial layer and the metal contact layer comprises about 75% of the metal and about 25% of a chalcogen.

In twenty-fifth example, an atomic composition of the metal contact layer, at the interface between the epitaxial layer and the metal contact layer, comprises a first percentage of the metal and a second percentage of a chalcogen, wherein the first percentage is at least about 1.3 times the second percentage.

In a twenty-sixth example, an atomic composition of the metal contact layer, at the interface between the epitaxial layer and the metal contact layer, comprises a first percentage of a metal and a second percentage of a chalcogen, wherein the first percentage is at least about 1.5 times the second percentage.

In a twenty-seventh example, an atomic composition of the metal contact layer, at the interface between the epitaxial layer and the metal contact layer, comprises a first percentage of the metal and a second percentage of a chalcogen, wherein the first percentage is between about 1.3 to about 3.3 times the second percentage.

In a twenty-eighth example, an atomic composition of the metal contact layer, at the interface between the epitaxial layer and the metal contact layer, comprises a first percentage of the metal and a second percentage of a chalcogen, wherein the first percentage is between about 1.5 to about 3 times the second percentage.

In a twenty-ninth example, an atomic composition of the metal contact layer, at the interface between the epitaxial layer and the metal contact layer, comprises a first percentage of the metal and a second percentage of a chalcogen, wherein the first percentage is about 1.5, 2, or 3 times the second percentage.

In a thirtieth example, the atomic composition of the metal contact layer further comprises from about 5% to about 20% phosphorous.

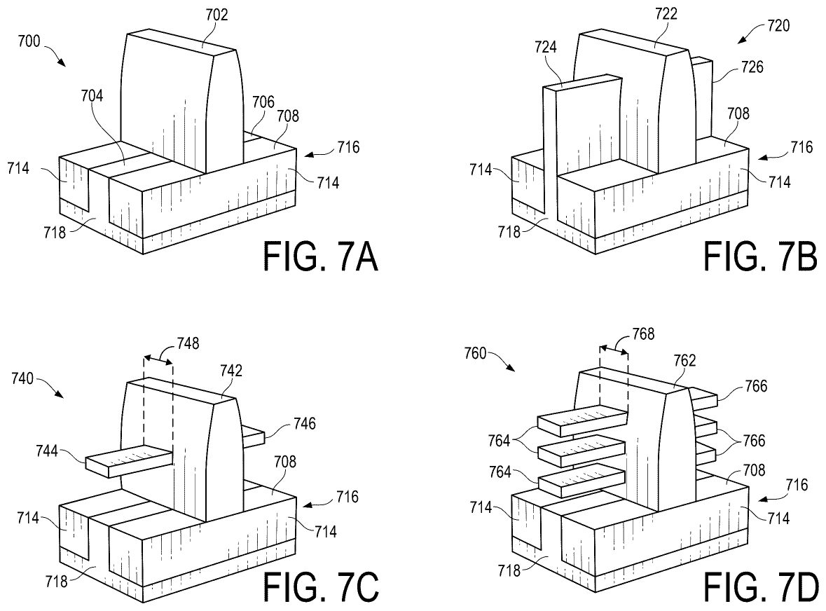

The chalcogen-doped NMOS source and drain regions disclosed herein can be part of any type of transistor, such as a planar FET, a FinFET, a gate-all-around FET (GAAFET), or stacked GAAFET (e.g., transistors 700, 720, 740, and 760 illustrated FIGS. 7A-7D).

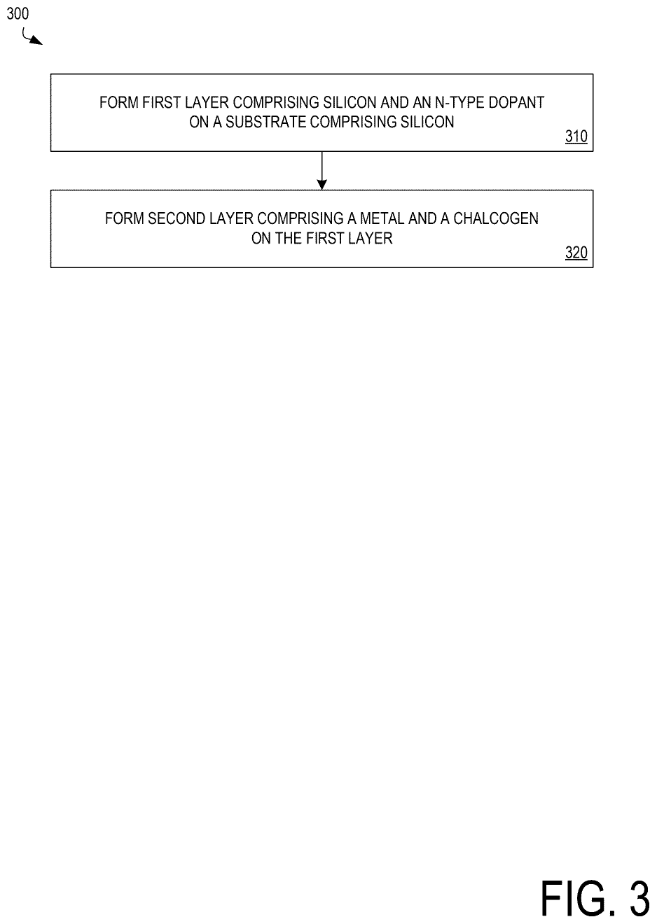

FIG. 3 is a first example method of forming chalcogen-doped NMOS source and drain contacts. The method 300 can be formed by, for example, an integrated circuit component manufacturer. At stage 310, a first layer comprising silicon and an n-type dopant is formed, the first layer located on a substrate comprising silicon. At stage 320, a second layer comprising a metal and a chalcogen is formed, at least a portion of the second layer located on the first layer. In other embodiments, the method 300 can comprise additional stages. For example, the method 300 can further comprise forming a third layer located on the second layer, the third layer comprising tungsten, cobalt, titanium, gold, aluminum, molybdenum, chromium, or nickel.

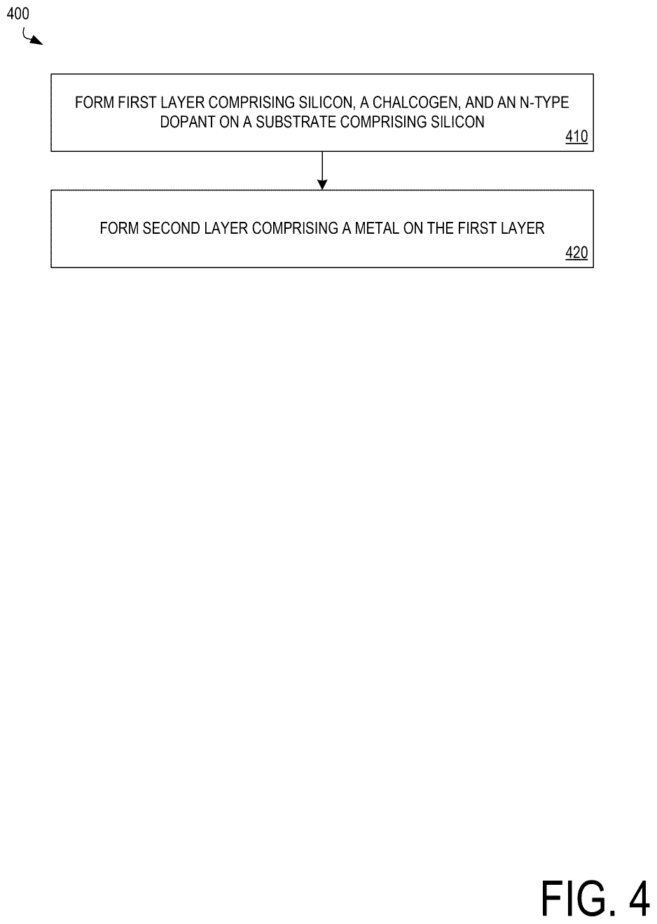

FIG. 4 is a second example method of forming chalcogen-doped NMOS source and drain contacts. The method 400 can be formed by, for example, an integrated circuit component manufacturer. At stage 410, a first layer comprising silicon, a chalcogen, and an n-type dopant is formed, wherein the first layer is located on a substrate comprising silicon. At stage 420, a second layer comprising a metal is formed, at least a portion of the second layer located on the first layer. In other embodiments, the method 400 can comprise additional stages. For example, forming the first layer can comprise: forming an epitaxial layer comprising the silicon and the n-type dopant; and forming, via a chemical vapor deposition process, a surface layer on a surface of the epitaxial layer, where the chemical vapor deposition process comprising flowing a silicon precursor and a chalcogen precursor comprising the chalcogen over the surface of the first layer, wherein the first layer comprises the epitaxial layer and the surface layer. In another example, the method 400 can further comprise forming a third layer located on the second layer, the third layer comprising tungsten, cobalt, titanium, gold, aluminum, molybdenum, chromium, or nickel.

Chalcogen-doped NMOS source and drain regions as described herein can be used in any processor unit, integrated circuit component, or computing system described or referenced herein. Such source and drain regions can be fabricated as part of an integrated circuit structure. The integrated circuit structure can comprise a die substrate, such as a die substrate comprising silicon, and one or more interconnect or metal layers. NMOS source and drain regions formed as described herein can connect to a line of an interconnect or metal layer by a via or by being positioned adjacent to a line of a metal layer. The integrated circuit structure can comprise other types of devices, such as electronic transistors (transistors such as CMOS transistors that operate through control of the flow of electric current and that do not rely upon the switching of the magnetization of a layer or component for operation) and/or magnetoelectric spin-orbit (MESO) devices that use magnetoelectric switching to convert an input voltage/charge into a magnetic spin state (e.g., charge-to-spin conversion) and further uses spin-orbit transduction to convert the magnetic spin state back into an output charge/voltage (e.g., spin-to-charge conversion). An integrated circuit component comprising source and drain regions formed as described herein can be attached to a printed circuit board. In some embodiments, one or more additional integrated circuit components can be attached to the circuit board, such as one or more additional integrated circuit components (e.g., processors, memory), battery, and/or antenna. In some embodiments, the printed circuit board and the integrated circuit component can be located in a computing device that comprises a housing that encloses the printed circuit board and the integrated circuit component.

It is to be understood that drawings illustrate idealized versions of structure lines. In actual lines, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

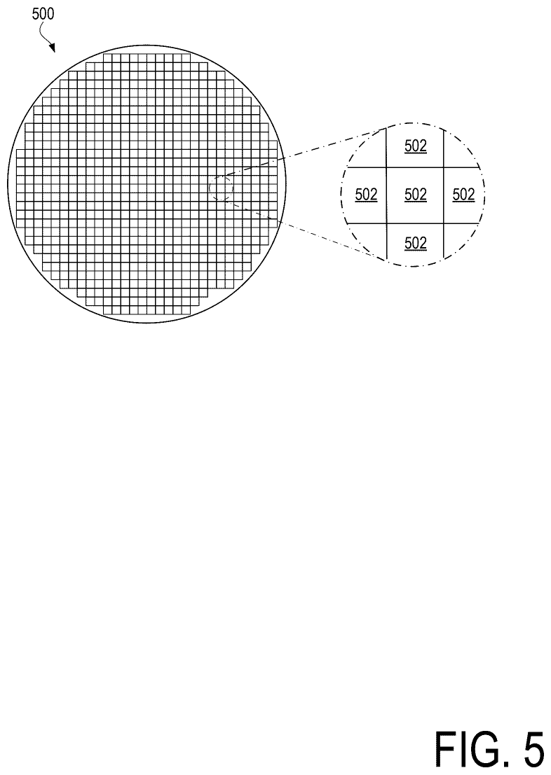

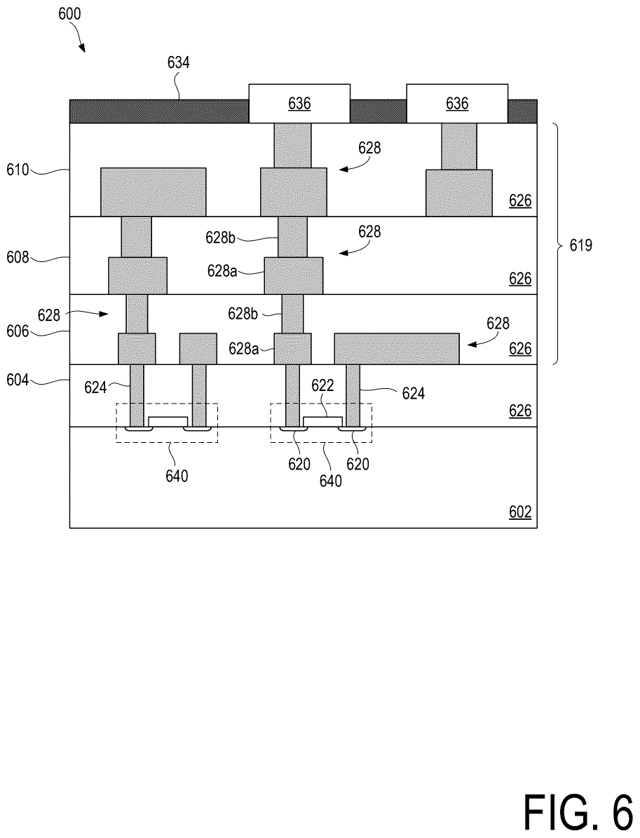

FIG. 5 is a top view of a wafer 500 and dies 502 in which any of the chalcogen-doped source and drain regions disclosed herein may be included. The wafer 500 may be composed of semiconductor material and dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The dies 502 may include one or more transistors (e.g., transistors 640 of FIG. 6, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 500 or the dies 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array.

FIG. 6 is a cross-sectional view of an integrated circuit structure 600 that may include any of the chalcogen-doped source and drain regions disclosed herein. Multiple instances of the integrated circuit structure 600 may be included in the dies 502 (FIG. 5). The integrated circuit structure 600 may be formed on a die substrate 602. The die substrate 602 may be a semiconductor substrate composed of semiconductor material including, for example, n-type or p-type materials (or a combination of both). The die substrate 602 may include, for example, a crystalline substrate formed using a bulk silicon or a silicon-on-insulator (SOI) substructure. In some embodiments, the die substrate 602 can comprise a layer of silicon on top of an SOI layer with bulk silicon below the SOI layer. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit structure 600 may be used. The die substrate 602 may be part of a singulated die (e.g., dies 502 of FIG. 5) or a wafer (e.g., wafer 500 of FIG. 5).

The integrated circuit structure 600 may include device layer 604 disposed on the die substrate 602. The device layer 604 may include features of transistors 640 (e.g., metal oxide semiconductor field-effect transistors (MOSFETs)) formed on the die substrate 602. The transistors 640 may include, for example, source and drain regions (S/D regions 620), a gate 622 to control current flow between the S/D regions 620, and S/D contacts 624 to route electrical signals to and from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

FIGS. 7A-7D are perspective views of example planar, FinFET, gate-all-around, and stacked gate-all-around transistors. The transistors illustrated in FIGS. 7A-7D are formed on a substrate 716 having a substrate surface 708 and a bulk region 718. Isolation regions 714 separate the source and drain regions of the transistors from other transistors.

FIG. 7A is a perspective view of an example transistor 700 comprising a gate 702 that controls current flow between a source region 704 and a drain region 706. The transistor 700 is planar in that the source region 704, the drain region 706 and the substrate surface 708 lie in the same plane.

FIG. 7B is a perspective view of an example transistor 720 comprising a gate 722 that controls current flow between a source region 724 and a drain region 726. The transistor 720 is non-planar in that the source region 724 and the drain region 726 comprise “fins” that extend upwards from the substrate surface 708. The transistor 720 can be referred to as a FinFET. As the gate 722 encompasses three sides of the fin that extends from the source region 724 to the drain region 726, the transistor 720 can be considered a tri-gate transistor. FIG. 7B illustrates one S/D fin extending through the gate 722, but multiple S/D fins can extend through the gate of a FinFET transistor.

FIG. 7C is a perspective view of a transistor 740 comprising a gate 742 that controls current flow between a source region 744 and a drain region 746. The transistor 740 is non-planar in that the source region 744 and the drain region 746 lie in a different plane than the substrate surface 708. As the gate 742 encompasses all sides of the channel region of the transistor 740 that extends from the source region 744 to the drain region 746, the transistor 740 can be referred to as a gate-all-around (GAA) transistor.

FIG. 7D is a perspective view of a transistor 760 comprising a gate 762 that controls current flow between multiple elevated source regions 764 and multiple elevated drain regions 766. The transistor 760 is a stacked GAA transistor as the gate controls the flow of current between multiple elevated S/D regions stacked on top of each other. The transistors 740 and 760 are considered gate-all-around transistors as the gates encompass all sides of the channel regions of the transistor that extends from the source regions to the drain regions. The transistors 740 and 760 can alternatively be referred to as nanowire, nanosheet, or nanoribbon transistors depending on the width (e.g., widths 748 and 768 of transistors 740 and 760, respectively) of the channel regions extending through the gate.

Returning to FIG. 6, transistors 640 may include a gate 622 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 7B, the gate electrode may have an upside-down U-shape that includes a top portion substantially parallel to the surface of the die substrate 602 and two side portions that are substantially perpendicular to the top surface of the die substrate 602. In other embodiments, such as the planar FET illustrated in FIG. 7A, at least one of the metal layers that form the gate electrode may be a planar layer that is substantially parallel to the top surface of the die substrate 602 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 620 may be formed within the die substrate 602 adjacent to the gate 622 of transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse further into the die substrate 602 may follow the ion implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or information-carrying signals (e.g., input/output (I/O) signals, may be routed to and/or from devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with interconnect structures 628 of the interconnect layers 606-610. The one or more interconnect layers 606-610 may form a metallization stack 619 (which can also be referred to as an “ILD stack” (inter-layer dielectric stack)) of the integrated circuit structure 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit structures having more or fewer interconnect layers than depicted.

In some embodiments, the interconnect structures 628 may include traces or lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, lines 628a of different interconnect layers 606-610 are electrically coupled by vias 628b.

The interconnect layers 606-610 may include a dielectric material 626 within which the interconnect structures 628 are disposed, as shown in FIG. 6. In some embodiments, dielectric material 626 in different ones of the interconnect layers 606-610 may have different compositions; in other embodiments, the composition of the dielectric material 626 between different interconnect layers 606-610 may be the same. The device layer 604 may include a dielectric material 626 within which the transistors 640 are disposed and upon which a bottom layer of the metallization stack is located. The dielectric material 626 that is part of the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (which can be referred to as a Metal 1 or “M1” layer) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (which can be referred to as a Metal 2 or “M2” layer) may be formed directly on the first interconnect layer 606. In some embodiments, the second interconnect layer 608 may include vias 628b to couple the lines 628a of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (which can be referred to as a Metal 3 or “M3” layer) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit structure 600 (i.e., farther away from the device layer 604) may be thicker than the interconnect layers that are lower in the metallization stack 619, with lines 628a and vias 628b in the higher interconnect layers being thicker than those in the lower interconnect layers.

The integrated circuit structure 600 may include a solder resist material 634 (e.g., polyimide or similar material) and conductive contacts 636 formed on the stack of interconnect layers 606-610. In FIG. 6, the conductive contacts 636 are illustrated as taking the form of bond pads. The conductive contacts 636 may be electrically coupled with interconnect structures 628 of the top-most layer in the metallization stack 619 and configured to route electrical signals between the transistors 640 and components external to the integrated circuit structure 600. For example, solder bonds may be formed on the conductive contacts 636 to mechanically and/or electrically couple an integrated circuit component comprising the integrated circuit structure 600 with another component (e.g., a printed circuit board). The integrated circuit structure 600 may include additional or alternate structures to route electrical signals from the interconnect layers 606-610; for example, the conductive contacts 636 may include other analogous features (e.g., posts) that can route the electrical signals between the transistors 640 and external components.

In some embodiments in which the integrated circuit structure 600 is part of a double-sided die, the integrated circuit structure 600 may include a second metallization stack (not shown) located on the opposite side of the die substrate 602 from the device layer 604. This second metallization stack may include multiple interconnect layers as discussed above with reference to the interconnect layers 606-610. Through-silicon vias (TSVs) that extend through the die substrate 602 can provide electrically conductive pathways from the transistors 640 to the second metallization stack and the second metallization stack can electrically couple the TSVs to additional conductive contacts (not shown) located on the opposite side of the integrated circuit structure 600 from the conductive contacts 636.

In some embodiments, TSVs extending through the die substrate 602 can be used for routing power and ground signals from conductive contacts located on the opposite side of the integrated circuit structure 600 from the conductive contacts 636 to the transistors 640 and any other components integrated into the integrated circuit structure 600, and the metallization stack 619 can be used to route information-carrying signals from the conductive contacts 636 to transistors 640 and any other components integrated into the integrated circuit structure 600. Put another way, the routing of power and ground signals to the transistors 640 can be separated (via a back-side or bottom-side metallization stack and TSVs) from the routing of information-carrying signals to the transistors. The power and ground signals are provided by a back-side or bottom-side metallization stack and TSVs, and information-carrying signals are provided by a top-side metallization stack (e.g., metallization stack 619).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

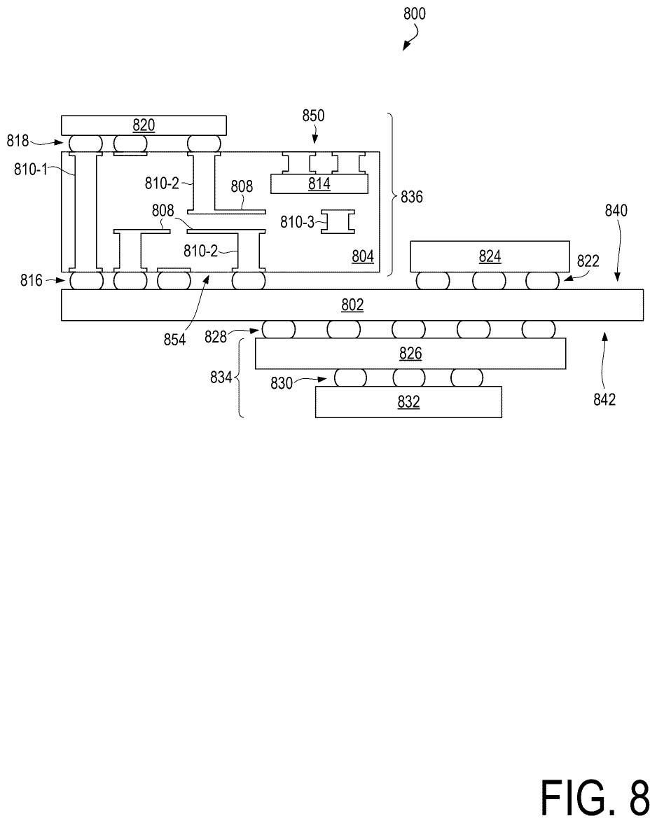

FIG. 8 is a cross-sectional view of an integrated circuit device assembly 800 that may include any of the chalcogen-doped source or drain regions disclosed herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and a second face 842 of the circuit board 802, the second face 842 opposing the first face 840. Generally, components may be disposed on either or both of the first face 840 and the second face 842 of the circuit board 802.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 802. In other embodiments, the circuit board 802 may be a non-PCB substrate.

The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802 and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.)

The package-on-interposer structure 836 may include an integrated circuit component 820 coupled to an interposer 804. The interposer 804 may provide an intervening substrate used to bridge the circuit board 802 and the integrated circuit component 820. The integrated circuit component 820 is coupled to the interposer 804 by coupling components 818. The coupling components 818 may take any suitable form, such as the forms discussed above with reference to the coupling components 816. Although FIG. 8 shows just one integrated circuit component attached to the interposer, multiple integrated circuit components may be coupled to the interposer 804. Additional interposers may be coupled to the interposer 804.

The integrated circuit component 820 may be a packaged or unpacked integrated circuit product that includes one or more integrated circuit dies (e.g., the die 502 of FIG. 5, a die comprising the integrated circuit structure 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider or narrower pitch or reroute a connection to a different connection. For example, the interposer 804 may couple coupling components 818 having a first pitch to coupling components 816 having a wider pitch than the first pitch. In the embodiment illustrated in FIG. 8, the integrated circuit component 820 and the circuit board 802 are attached to opposing sides of the interposer 804. In other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias, including but not limited to through hole vias 810-1 (that extend from a first face 850 of the interposer 804 to a second face 854 of the interposer 804), blind vias 810-2 (that extend from the first face 850 or the second face 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 further includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

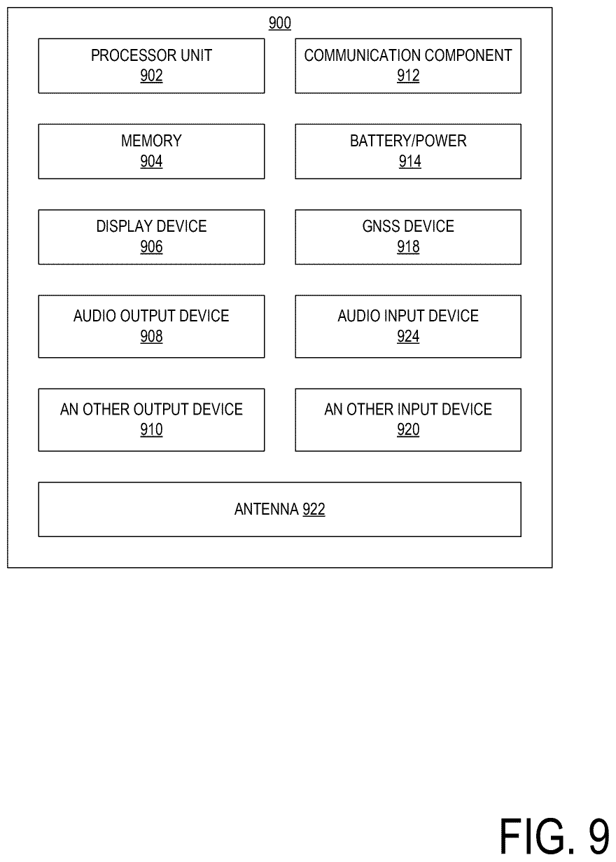

FIG. 9 is a block diagram of an example electrical device 900 that may include any of the chalcogen-doped source or drain regions disclosed herein. For example, any suitable ones of the components of the electrical device 900 may include one or more of the integrated circuit device assembly 800, integrated circuit component 820, or integrated circuit structure 600, integrated circuit dies 502 disclosed herein, and may be arranged in any of the microelectronic assemblies disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the one or more processor units 902. This memory may be used as cache memory (e.g., Level 1(L1 ), Level 2(L2 ), Level 3(L3 ), Level 4(L4 ), Last Level Cache (LLC)) and may include embedded dynamic random-access memory (eDRAM) or spin transfer torque magnetic random-access memory (STT-MRAM).

In some embodiments of the electrical device 900, a first one of the one or more processor units 902 can be heterogeneous or asymmetric to a second one of the one or more processor units 902 in the electrical device 900. There can be a variety of differences between the one or more processor units 902 in a system in terms of a spectrum of metrics of merit including architectural, microarchitectural, thermal, power consumption characteristics, and the like. These differences can effectively manifest themselves as asymmetry and heterogeneity among the one or more processor units 902 in the electrical device 900.

In some embodiments, the electrical device 900 may include a communication component 912. For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). In some embodiments, the electrical device 900 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such as speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System device (GNSS) (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 comprises an apparatus, comprising: a substrate comprising silicon; a first layer comprising silicon and an n-type dopant, the first layer located on the substrate; and a second layer comprising a metal and a chalcogen, at least a portion of the second layer located on the first layer, wherein the first layer and/or the second layer comprises an atomic composition of at least about 5% of the chalcogen at an interface between the first layer and the second layer.

Example 2 comprises the apparatus of Example 1, wherein the first layer comprises an atomic composition comprising from about 5% to about 50% of the chalcogen at an interface between the first layer and the second layer.

Example 3 comprises the apparatus of Example 1, wherein the first layer comprises an atomic composition comprising at least about 5% of the chalcogen at a point one nanometer into the first layer from the interface between the first layer and the second layer.

Example 4 comprises an apparatus, comprising: a substrate comprising silicon; a first layer comprising silicon and an n-type dopant, the first layer located on the substrate; and a second layer comprising a metal and a chalcogen, at least a portion of the second layer located on the first layer, wherein the first layer comprises an atomic composition comprising from about 5% to about 50% of the chalcogen at an interface between the first layer and the second layer.

Example 5 comprises the apparatus of Example 4, wherein the first layer comprises an atomic composition comprising at least about 5% of the chalcogen at a point one nanometer into the first layer from the interface between the first layer and the second layer.

Example 6 comprises a system comprising: an integrated circuit component comprising: a substrate comprising silicon; a first layer comprising silicon and an n-type dopant, the first layer located on the substrate; and a second layer comprising a metal and a chalcogen, at least a portion of the second layer located on the first layer, wherein the first layer comprises an atomic composition comprising at least about 5% of the chalcogen at a point one nanometer into the second layer from an interface between the first layer and the second layer; and a printed circuit board, the integrated circuit component attached to the printed circuit board.

Example 7 comprises the system of Example 6, wherein the first layer comprises an atomic composition comprising from about 5% to about 50% of the chalcogen at an interface between the first layer and the second layer.

Example 8 comprises the apparatus or system of any one of Examples 1, 4, and 6,wherein the second layer comprises an atomic composition comprising from about 5% to about 50% of the chalcogen at an interface between the first layer and the second layer.

Example 9 comprises the apparatus or system of any one of Examples 1, 4, and 6,wherein the first layer comprises an atomic composition comprising at least about 5% of the chalcogen at a point one nanometer into the first layer from the interface between the first layer and the second layer.

Example 10 comprises the apparatus or system of any one of Examples 1, 4, and 6,wherein the first layer comprises an atomic composition comprising at least about 5% of the chalcogen at a point three nanometers into the first layer from the interface between the first layer and the second layer.

Example 11 comprises the apparatus or system of any one of Examples 1, 4, and 6,wherein the first layer comprises an atomic composition comprising at least about 5% of the chalcogen at a point five nanometers into the first layer from the interface between the first layer and the second layer.

Example 12 comprises the apparatus or system of any one of Examples 1, 4, and 6,wherein the first layer comprises an atomic composition comprising at least about 30% of the chalcogen at an interface between the first layer and the second layer and less than about 5% of the chalcogen and from about 5% to about 20% phosphorous at a point one nanometer into the first layer from the interface between the first layer and the second layer.

Example 13 comprises the apparatus or system of any one of Examples 1, 4, and 6,wherein the first layer comprises an atomic composition comprising at least about 30% of the chalcogen at an interface between the first layer and the second layer and less than about 5% of the chalcogen and from about 5% to about 20% phosphorous at a point two nanometers into the first layer from the interface between the first layer and the second layer.

Example 14 comprises the apparatus or system of any one of Examples 1, 4, and 6,wherein the first layer comprises an atomic composition comprising at least about 30% of the chalcogen at an interface between the first layer and the second layer and less than about 5% of the chalcogen and from about 5% to about 20% phosphorous at a point five nanometers into the first layer from the interface between the first layer and the second layer.

Example 15 comprises the apparatus or system of any one of Examples 1, 4, and 6,wherein the first layer comprises an atomic composition comprising at least about 5% of the chalcogen at an interface between the first layer and the second layer and less than 0.01% of the chalcogen and from about 5% to about 20% phosphorous at a point 10 nanometers into the first layer from the interface between the first layer and the second layer.

Example 16 comprises the apparatus or system of any one of Examples 1, 4, and 6,wherein the first layer comprises an atomic composition comprising at least about 5% of the chalcogen at an interface between the first layer and the second layer and less than 0.01% of the chalcogen and from about 5% to about 20% phosphorous at a point 15 nanometers into the first layer from the interface between the first layer and the second layer.

Example 17 comprises the apparatus or system of any one of Examples 1, 4, and 6,wherein the first layer comprises an atomic composition comprising at least about 5% of the chalcogen at an interface between the first layer and the second layer and less than 0.01% of the chalcogen and from about 5% to about 20% phosphorous at a point 20 nanometers into the first layer from the interface between the first layer and the second layer.

Example 18 comprises the apparatus or system of any one of Examples 1, 4, and 6,wherein the first layer comprises an atomic composition comprising at least about 5% of the chalcogen at an interface between the first layer and the second layer and an atomic composition comprising less than about 5% of the chalcogen at a point one nanometer into the second layer one nanometer from the interface.

Example 19 comprises the apparatus or system of any one of Examples 1, 4, and 6,wherein the first layer comprises an atomic composition comprising at least about 30% of the chalcogen at an interface between the first layer and the second layer and an atomic composition comprising no more than about 5% of the chalcogen at a point three nanometers into the second layer two nanometers from the interface.

Example 20 comprises the apparatus or system of any one of Examples 1, 4, and 6, wherein the first layer comprises an atomic composition comprising at least about 30% of the chalcogen at an interface between the first layer and the second layer and an atomic composition comprising no more than about 5% of the chalcogen at a point into the second layer ten nanometers from the interface.

Example 21 comprises the apparatus or system of any one of Examples 1, 4, and 6, wherein the second layer further comprises phosphorous, the second layer comprising an atomic composition comprising a first percentage of the metal, a second percentage of the chalcogen, and a third percentage of phosphorous, wherein the second percentage is less than the first percentage and greater than the third percentage.

Example 22 comprises the apparatus or system of any one of Examples 1, 4, and 6, wherein, at an interface between the first layer and the second layer, the first layer comprising an atomic composition comprising a first percentage of the chalcogen and a second percentage of the n-type dopant, wherein the first percentage is at least twice the second percentage.

Example 23 comprises the apparatus or system of any one of Examples 1, 4, and 6, wherein an atomic composition of the second layer, at the interface between the first layer and the second layer, comprises at least about 60% of the metal and less than about 40% of the chalcogen.

Example 24 comprises the apparatus or system of any one of Examples 1, 4, and 6, wherein an atomic composition of the second layer, at the interface between the first layer and the second layer, comprises at least about 50% of the metal and less than about 50% of the chalcogen.

Example 25 comprises the apparatus or system of any one of Examples 1, 4, and 6, wherein an atomic composition of the second layer, at the interface between the first layer and the second layer, comprises from about 55% to about 80% of the metal and from about 20% to about 45% of the chalcogen.

Example 26 comprises the apparatus or system of any one of Examples 1, 4, and 6, wherein an atomic composition of the second layer, at the interface between the first layer and the second layer, comprises from about 60% to about 75% of the metal and from about 25% to about 40% of the chalcogen.

Example 27 comprises the apparatus or system of any one of Examples 1, 4, and 6,wherein an atomic composition of the second layer, at the interface between the first layer and the second layer, comprises: about 60% of the metal and about 40% of the chalcogen; about 67% of the metal and about 33% of the chalcogen; and about 75% of the metal and about 25% of the chalcogen.

Example 28 comprises the apparatus or system of any one of Examples 1, 4, and 6,wherein an atomic composition of the second layer, at the interface between the first layer and the second layer, comprises a first percentage of the metal and a second percentage of the chalcogen, wherein the first percentage is at least about 1.3 times the second percentage.

Example 29 comprises the apparatus or system of any one of Examples 1, 4, and 6,wherein an atomic composition of the second layer, at the interface between the first layer and the second layer, comprises a first percentage of the metal and a second percentage of the chalcogen, wherein the first percentage is at least about 1.5 times the second percentage.

Example 30 comprises the apparatus or system of any one of Examples 1, 4, and 6,wherein an atomic composition of the second layer, at the interface between the first layer and the second layer, comprises a first percentage of the metal and a second percentage of the chalcogen, wherein the first percentage is between about 1.3 to about 3.3 times the second percentage.

Example 31 comprises the apparatus or system of any one of Examples 1, 4, and 6,wherein an atomic composition of the second layer, at the interface between the first layer and the second layer, comprises a first percentage of the metal and a second percentage of the chalcogen, wherein the first percentage is between about 1.5 to about 3 times the second percentage.

Example 32 comprises the apparatus or system of any one of Examples 1, 4, and 6,wherein an atomic composition of the second layer, at the interface between the first layer and the second layer, comprises a first percentage of the metal and a second percentage of the chalcogen, wherein the first percentage is about 1.5, 2, or 3 times the second percentage.

Example 33 comprises the apparatus or system of any one of Examples 28-32, wherein the second layer further comprises phosphorous and the atomic composition of the second layer further comprises from about 5% to about 20% phosphorous.

Example 34 comprises the apparatus or system of any one of Examples 1-33, wherein the second layer further comprises phosphorous and the atomic composition of the second layer comprises from about 5% to about 20% atomic percentage of phosphorous.

Example 35 comprises the apparatus or system of any one of Examples 1-34, wherein the second layer comprises the n-type dopant.

Example 36 comprises the apparatus or system of any one of Examples 1-35, wherein the n-type dopant is phosphorous.

Example 37 comprises the apparatus or system of any one of Examples 1-36, wherein the chalcogen is tellurium.

Example 38 comprises the apparatus or system of any one of Examples 1-37, wherein the chalcogen is selenium, or sulfur.

Example 39 comprises the apparatus or system of any one of Examples 1-38, wherein the metal is titanium.

Example 40 comprises the apparatus or system of any one of Examples 1-38, wherein the metal is titanium; the chalcogen is tellurium, selenium, or sulfur; and the n-type dopant is phosphorous.

Example 41 comprises the apparatus or system of any one of Examples 1-38, wherein the metal comprises tantalum, tungsten, scandium, zirconium, or aluminum.

Example 42 comprises the apparatus or system of any one of Examples 1-41, wherein a thickness of the portion of the second layer located on the first layer is no more than about two nanometers.

Example 43 comprises the apparatus or system of any one of Examples 1-41, wherein a thickness of the portion of the second layer located on the first layer is no more than about three nanometers.

Example 44 comprises the apparatus or system of any one of Examples 1-43, further comprising a third layer located on the second layer, the third layer comprising tungsten, cobalt, titanium, gold, aluminum, molybdenum, chromium, or nickel.

Example 45 comprises the apparatus or system of Example 44, further comprising a fourth layer positioned between the second layer and the third layer, the fourth layer comprising titanium and nitrogen.

Example 46 comprises the apparatus or system of Example 44, further comprising a fourth layer positioned between the second layer and the third layer, the fourth layer comprising:
indium and oxygen; tungsten and nitrogen; titanium and nitrogen; or ruthenium.
Example 47 comprises the apparatus or system of any one of Examples 1-46, wherein the first layer is a source or drain region of a transistor.
Example 48 comprises the apparatus or system of Example 47, wherein the transistor is a planar field-effect transistor (FET), a FinFET, a gate-all-around FET (GAAFET), or a stacked gate-all-around FET.
Example 49 comprises the apparatus or system of any one of Examples 1-48 wherein the apparatus is an integrated circuit component.
Example 50 comprises the apparatus or system of Example 49, wherein the integrated circuit component is attached to a printed circuit board.
Example 51 comprises the apparatus or system of Example 50, wherein the integrated circuit component is a first integrated circuit component, the apparatus further comprising a second integrated circuit component, battery, and/or antenna attached to the printed circuit board.
Example 52 comprises the apparatus or system of any one of Examples 49-51, further comprising a housing that is part of a computing system, wherein the integrated circuit component is located within the housing.
Example 53 comprises the apparatus or system of any one of Examples 1-52, wherein the first layer is an epitaxial layer.
Example 54 comprises a method, comprising: forming a first layer comprising silicon and an n-type dopant, the first layer located on a substrate comprising silicon; and forming a second layer comprising a metal and a chalcogen, at least a portion of the second layer located on the first layer.
Example 55 comprises the method of Example 54, wherein forming the second layer comprises sputtering a target to form the second layer, the target comprising the metal and the chalcogen.
Example 56 comprises the method of Example 55, wherein the target comprises from about 1% to about 50% of the chalcogen by weight.
Example 57 comprises the method of Example 55, wherein the second layer further comprises the n-type dopant and the target further comprises the n-type dopant.
Example 58 comprises the method of Example 57, wherein the target comprises from about 1% to about 50% of the n-type dopant by weight.
Example 59 comprises the method of Example 54, wherein the second layer is formed by co-sputtering a first target comprising the metal and a second target comprising the chalcogen.
Example 60 comprises the method of Example 59, wherein the second layer further comprises phosphorous, and the first target or the second target comprises between from about 1% to about 50% of phosphorous by weight.

Example 61 comprises the method of any one of Examples 54-60, wherein a thickness of the portion of the second layer located on the first layer is about two nanometers or less.

Example 62 comprises the method of any one of Examples 54-60wherein a thickness of the portion of the second layer on the first layer is about three nanometers or less.

Example 63 comprises a method, comprising: forming a first layer comprising silicon, a chalcogen, and an n-type dopant, wherein the first layer is located on a substrate comprising silicon; and forming a second layer comprising a metal, at least a portion of the second layer located on the first layer.

Example 64 comprises the method of Example 63, wherein forming the first layer comprises flowing a precursor comprising the chalcogen over a surface of the first layer to dope the surface of the first layer with the chalcogen.

Example 65 comprises the method of Example 63, wherein forming the first layer comprises: forming an epitaxial layer comprising the silicon and the n-type dopant; and forming, via a chemical vapor deposition process, a surface layer on a surface of the epitaxial layer, where the chemical vapor deposition process comprising flowing a silicon precursor and a chalcogen precursor comprising the chalcogen over the surface of the epitaxial layer, wherein the first layer comprises the epitaxial layer and the surface layer.

Example 66 comprises the method of Example 65, wherein the surface layer further comprises the n-type dopant and the chemical vapor deposition process further comprises an n-type dopant precursor comprising the n-type dopant.

Example 67 comprises the method of any one of Examples 65, wherein a thickness of the surface layer is about 5 nanometers or less.

Example 68 comprises the method of any one of Examples 54-67, wherein the n-type dopant is phosphorous.

Example 69 comprises the method of any one of Examples 54-68, wherein the chalcogen is tellurium, selenium, or sulfur.

Example 70 comprises the method of any one of Examples 54-69, wherein the metal is titanium, tantalum, zirconium, hafnium, aluminum, tantalum or nitrogen.

Example 71 comprises the method of any one of Examples 54-69, wherein the metal is titanium, the chalcogen is tellurium, selenium, or sulfur, and the n-type dopant is phosphorous.

Example 72 comprises the method of any one of Examples 54-71, further comprising forming a third layer located on the second layer, the third layer comprising tungsten, cobalt, titanium, gold, aluminum, molybdenum, chromium, or nickel.

Example 73 comprises the method of any one of Examples 54-72, wherein the first layer is a source or drain region of a transistor.

1. An apparatus, comprising:
a substrate comprising silicon;
a first layer comprising silicon and an n-type dopant, the first layer located on the substrate; and
a second layer comprising a metal and a chalcogen, at least a portion of the second layer located on the first layer, wherein the first layer and/or the second layer comprises an atomic composition of at least about 5% of the chalcogen at an interface between the first layer and the second layer.

2. The apparatus of claim 1, wherein the first layer comprises an atomic composition comprising from about 5% to about 50% of the chalcogen at an interface between the first layer and the second layer.

3. The apparatus of claim 1, wherein the second layer further comprises phosphorous, the second layer comprising an atomic composition comprising a first percentage of the metal, a second percentage of the chalcogen, and a third percentage of phosphorous, wherein the second percentage is less than the first percentage and greater than the third percentage.

4. The apparatus of claim 1, wherein, at an interface between the first layer and the second layer, the first layer comprising an atomic composition comprising a first percentage of the chalcogen and a second percentage of the n-type dopant, wherein the first percentage is at least twice the second percentage.

5. The apparatus of claim 1, wherein the chalcogen is tellurium, selenium, or sulfur.

6. The apparatus of claim 1, wherein the metal comprises titanium, tantalum, tungsten, scandium, zirconium, or aluminum.

7. The apparatus of claim 1, wherein the first layer is a source or drain region of a transistor.

8. The apparatus of claim 1, wherein the apparatus is an integrated circuit component attached to a printed circuit board.

9. An apparatus, comprising:
a substrate comprising silicon;
a first layer comprising silicon and an n-type dopant, the first layer located on the substrate; and
a second layer comprising a metal and a chalcogen, at least a portion of the second layer located on the first layer, wherein the first layer comprises an atomic composition comprising from about 5% to about 50% of the chalcogen at an interface between the first layer and the second layer.

10. The apparatus of claim 9, wherein the second layer comprises an atomic composition comprising from about 5% to about 50% of the chalcogen at an interface between the first layer and the second layer.

11. The apparatus of claim 9, wherein the first layer comprises an atomic composition comprising at least about 5% of the chalcogen at a point three nanometers into the first layer from the interface between the first layer and the second layer.

12. The apparatus of claim 9, wherein the first layer comprises an atomic composition comprising at least 30% of the chalcogen at an interface between the first layer and the second layer and an atomic composition comprising no more than 5% of the chalcogen at a point three nanometers into the second layer from the interface.

13. The apparatus of claim 9, wherein the chalcogen is tellurium, selenium, or sulfur;
and the metal comprises titanium, tantalum, tungsten, scandium, zirconium, or aluminum.

14. The apparatus of claim 9, wherein the apparatus is an integrated circuit component attached to a printed circuit board.

15. A system comprising:
an integrated circuit component comprising:
a substrate comprising silicon;
a first layer comprising silicon and an n-type dopant, the first layer located on the substrate; and
a second layer comprising a metal and a chalcogen, at least a portion of the second layer located on the first layer, wherein the first layer comprises an atomic composition comprising at least about 5% of the chalcogen at a point one nanometer into the second layer from an interface between the first layer and the second layer; and
a printed circuit board, the integrated circuit component attached to the printed circuit board.

16. The system of claim 15, wherein the second layer comprises an atomic composition comprising from about 5% to about 50% of the chalcogen at an interface between the first layer and the second layer.

17. The system of claim 15, wherein an atomic composition of the second layer, at the interface between the first layer and the second layer, comprises at least 60% of the metal and less than 40% of the chalcogen.

18. The system of claim 15, wherein an atomic composition of the second layer, at the interface between the first layer and the second layer, comprises a first percentage of the metal and a second percentage of the chalcogen, wherein the first percentage is at least about 1.5 times the second percentage.

19. The system of claim 15, wherein the second layer further comprises phosphorous and the atomic composition of the second layer further comprises from about 5% to about 20% phosphorous.

20. The system of claim 15, wherein the chalcogen is tellurium, selenium, or sulfur; and the metal comprises titanium, tantalum, tungsten, scandium, zirconium, or aluminum.
